(19) United States
(12) Patent Application Publication
(10) Pub. No.: US 2015/0276839 A1
(43) Pub. Date: Oct. 1, 2015

(54) WORST CASE JITTER PREDICTION METHOD USING STEP RESPONSE

(71) Applicant: QUALCOMM Incorporated, San Diego, CA (US)

(72) Inventors: Chun-Chen Liu, San Diego, CA (US); Oscar Ming Kin Law, San Diego, CA (US); Zhengyu Duan, San Diego, CA (US)

(73) Assignee: QUALCOMM Incorporated, San Diego, CA (US)

(21) Appl. No.: 14/242,698

(22) Filed: Apr. 1, 2014

(51) Int. Cl. G01R 29/26; G06F 17/11; G06F 17/50

(52) U.S. Cl. CPC G01R 29/26; G06F 17/5036; G06F 17/11

(57) ABSTRACT

A method operational within a simulation environment is provided for estimating or predicting jitter. At least two step functions are defined to approximate a worst-case jitter condition for a simulated electrical interconnect or a simulated electrical path. Each of the at least two step functions is sequentially used as input signals to the simulated electrical interconnect or path to obtain at least two corresponding step function responses. Jitter for the simulated electrical interconnect or path is predicted based on the at least two step function responses.

### BACKGROUND

1. Field

Various features relate to simulating analog behavior within a simulator, and more specifically to a method and/or technique to replace pseudo-randomly generated input signals with a plurality of step functions within a simulator.

2. Background

Interchip communication is expected to exceed 30 GHz in 2015. One challenge in this era is low-power and high-frequency effect. In these high frequency environments, high lossy, latency and parasitism effects make interchip interconnections complicated. During development of chips, it is often desirable to test interconnects and other paths in order to minimize jitter. However, traditional jitter simulations take a long time and cannot be easily predicted. For instance, in order to identify a worst case jitter and eye-high, over 10000 bit random impulse input simulations may be necessary, which makes such simulation very time consuming.

Jitter is how early or late a signal transition is with reference to when it should transition. Jitter is undesirable because it causes transmission errors and/or limits the transmission speed. Jitter is often quantized in terms of a bit error rate (BER) target. Bit errors can also be caused by voltage noise. If the momentary noise voltage exceeds the noise margin, a wrong value can be sampled even if the sampling takes place at the correct moment in time. Jitter is used to characterize a system since it takes longer to characterize bit error rate (BER). Also, jitter provides some information about the cause of the errors while BER does not.

Eye pattern is an effective method of measuring time distortion of a signal through a transmission medium or circuit. The eye pattern is displayed in an oscilloscope. An eye pattern is the superposition, over one unit interval, of all the Zero-to-One and One-to-Zero transitions, each preceded and followed by various combinations of One and Zero, and also constant One and Zero levels. An eye pattern is formed when the superposition of signal unit intervals align with each other (e.g., indicating no jitter distortion). On the other hand, a distorted eye pattern or no eye pattern is formed when jitter is present.

For inter/intra chip interconnect, the data sequence can be generated by a pseudo-random sequence/signal generator (PRSG), which may be a digital shift register with feedback connected to produce a maximum length sequence. However, identifying a worst-case scenario for jitter is time-consuming, especially when using a pseudo-random sequence generator to generate a test input signal.

Therefore, a method and/or technique is needed to simulate real number traffic, as in RF/analog/mixed-signal, within an event-driven digital simulator.

### SUMMARY

A method and technique operational within a simulator are provided for substituting a pseudo-random number generated input signal with two or more step functions to characterize or predict jitter for a circuit, component, element, path, or interconnect being simulated. At least two step functions are defined to approximate a worst case jitter condition for a simulated electrical interconnect or a simulated electrical path 1402. The at least two step functions are sequentially used as input signals to the simulated electrical interconnect or path to obtain at least two corresponding step function responses 1404. Jitter for the simulated electrical interconnect or simulated electrical path may be predicted based on the at least two step function responses 1406.

In one example, a rise time for the at least two step functions may be adjusted to approximate a worst case jitter condition. In another example, a noise signal may be added to the at least two step functions to approximate a worst case jitter condition.

In one example, the at least two step functions include a first step function and a second step function. Predicting jitter may include: (a) estimating a first reference voltage, a first saturation voltage, and a first peak voltage for a first response corresponding to the first step function, (b) obtaining a first eye voltage based on the first reference voltage, the first saturation voltage, and the first peak voltage, (c) estimating a second reference voltage, a second saturation voltage, and a second peak voltage for a second response corresponding to the second step function, (d) obtaining a second eye voltage based on the second reference voltage, the second saturation voltage, and the second peak voltage, and/or (e) estimating the jitter based on a difference between the first eye voltage and the second eye voltage.

In another example, the at least two step functions may include a first step function and a second step function. The method may further comprise: (a) adding a plurality of different noise signals to distinct instances of the first step function and second step function, where each of the different noise signals approximate different levels of noise, and/or (b) using distinct instances of the first step function and second step function as inputs to the simulated electrical path. Predicting jitter may include: (a) obtaining a plurality of distinct responses for the distinct instances of the first step function and second step function; (b) estimating a reference voltage, a saturation voltage, and a peak voltage for each response corresponding to each instance of the first and second step functions; (c) obtaining eye voltages for each response based on the first reference voltage, the first saturation voltage, and the first peak voltage; and/or (d) estimating the jitter based on a maximum difference between the different pairs of eye voltages.

In some instances, the at least two step functions may be defined with wideband frequency signal characteristics when used as input signals to the simulated electrical interconnect.

In other instances, the at least two step functions may be defined with low frequency signal characteristics when used as input signals to the simulated electrical path.

The at least two step functions used for the simulated electrical interconnect may be distinct from the at least two step functions used for the simulated electrical path. The at least two step functions may replace a pseudo-random sequence as input signals to the simulated electrical interconnect or path.

### BRIEF DESCRIPTION OF DRAWINGS

FIG. 1 is a block diagram illustrating an exemplary simulation environment which may be configured to predict worst-case jitter.

FIG. 2 illustrates the creation of exemplary eye patterns.

FIG. 3 illustrates how a binary signal corresponding to one bit may be decomposed into a first step function, a second step function, and a DC noise level.

FIG. 4 illustrates how a binary signal corresponding to multiple bits may be decomposed into a first step function, a second step function, and a DC noise level.

FIG. 5 is a diagram illustrating how a digital signal may be replaced by a set of input functions that serve as input to a simulated interconnect or clock/data path with non-linear elements to obtain an output response.

FIG. 6 is a diagram illustrating how a digital signal may be replaced by a set of input functions that serve as input to a simulated interconnect to predict jitter.

FIG. 7 illustrates the output response graph of FIG. 6.

FIG. 8 is a diagram illustrating how a digital signal and power supply noise may be replaced by a set of input step functions and a DC noise signal that serve as input to a simulated clock/data path with non-linear elements to predict jitter.

FIG. 9 illustrates the input step signals and the DC noise signal of FIG. 8.

FIG. 10 illustrates how the input signals of FIG. 9 may be used to generate a plurality of output responses.

FIG. 11 illustrates an eye diagram 1116 formed from the responses of FIG. 10.

FIG. 12 illustrates the results of a simulation model for an inter/intra chip interconnect path.

FIG. 13 is a block diagram illustrating a device that implements a digital simulator in which the input signals are generated from step functions.

FIG. 14 is a flow diagram illustrating a method operational within a simulator for substituting a pseudo-random number generated input signal with two step functions to characterize or predict jitter for a circuit, component, element, path, or interconnect being simulated.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures, and techniques may not be shown in detail in order not to obscure the aspects of the disclosure.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation.

### Overview

According to one aspect, rather than using a pseudo-randomly generated input signal to predict worst-case jitter, a combination of two or more step function responses are used to generate an input signal within a simulator environment. That is, in this approach, a set of input signals is formed from: (a) a DC input signal representing a power supply noise, (b) a first step function representing a first part of a clock signal or binary signal, and/or (c) a second step function input representing a second part of the clock signal or binary signal. Each of these input signals may be processed sequentially by the simulator (i.e., each step function is used as an input signal to characterize path, element, component, interconnect or a circuit being simulated) and obtain individual outputs. These individual outputs may be characterized by three states, where each individual output may be characterized by a reference voltage, a maximum voltage, and a saturation voltage. By comparing at least two of the individual outputs (e.g., the outputs obtained from a first step function response and a second step function response) jitter and/or noise may be characterized, predicted, and/or estimated. In this manner, a worst-case scenario for jitter and/or noise may be generated by adjusting the corresponding step functions used as input signals to the simulation. Depending on the component(s), element(s), interconnect(s), or path(s) being tested in the simulation, various assumptions may be made in generating the step function inputs.

### Exemplary Simulation Environment

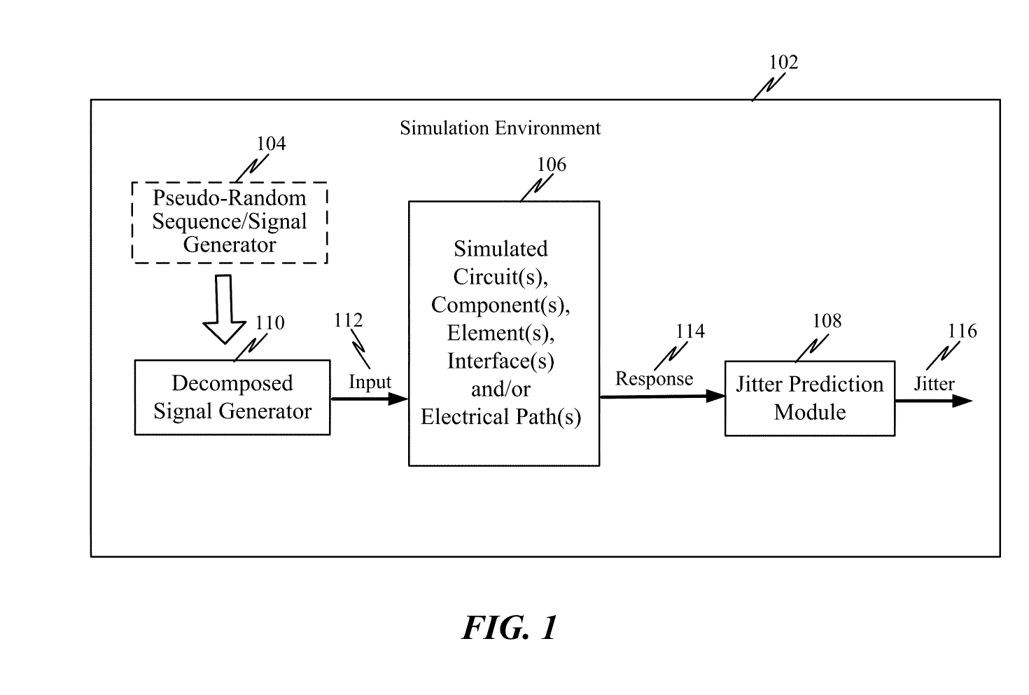

FIG. 1 is a block diagram illustrating an exemplary simulation environment which may be configured to predict worst-case jitter. The simulation environment 102 may implement a hardware description language (HDL) that may be used to model various systems. For example, the simulation environment 102 may serve to simulate electrical circuits, components (e.g., memory, semiconductor device, chip, processor, programmable-logic arrays, amplifiers, etc.), elements (e.g., capacitors, resistors, inductors, transistors, input/output drivers, etc.), interfaces (e.g., interconnection elements, bumps, solder points, connectors, etc.) and/or electrical paths (e.g., conductive routes, vias, etc.) 106.

One use of such simulation environment is to characterize the electrical properties (e.g., signal response, delay, jitter, etc.) of the simulated electrical circuits, components, elements, interfaces and/or electrical paths. For instance, such simulation(s) may be performed prior to manufacturing of such electrical circuits, components, elements, interfaces and/or electrical paths. In typical approaches, a pseudo-random sequence/signal generator (PRSG) 104 may be used to obtain a maximum length sequence or signal used as an input to characterize the electrical circuits, components, elements, interfaces and/or electrical paths. For example, the goal may be to identify a worst-case scenario for jitter. However, using the pseudo-random sequence/signal generator (PRSG) 104 to generate input signals is time-consuming as many/all sequence or signal iterations must be obtained and tested in order to identify the worst-case scenario for jitter (or other characteristic under test).

According to one feature, a decomposed signal generator 110 is used to generate an input signal 112 which is used to test the simulated electrical circuits, components, elements, interfaces, and/or electrical paths 106. The response 114 from the simulated electrical circuits, components, elements, interfaces, and/or electrical paths 106 may then be provided to a jitter prediction module 108 which serves to provide a jitter 116 estimate.

### Jitter

Jitter is how early or late a signal transition is with reference to when it should transition. Jitter is undesirable because it causes transmission errors and/or limits the transmission speed/rate. Jitter is often quantized in terms of a bit error rate (BER) target. Bit errors can also be caused by voltage noise. If the momentary noise voltage exceeds the noise margin, a wrong value can be sampled even if the sampling takes place at the correct moment in time. Jitter may be used to characterize a system since it takes longer to characterize/obtain a bit error rate (BER). For instance, a BER measurement may take hours or days as a large number of bits are run through a simulated electrical circuits, components, elements, interfaces, and/or electrical paths to accumulate an error measurement.

Additionally, BER gives little information about the mechanism that caused an error. However, jitter provides some information about the cause of the error, which permits improving the electrical circuits, components, elements, interfaces, and/or electrical paths being characterized.

### Eye Pattern

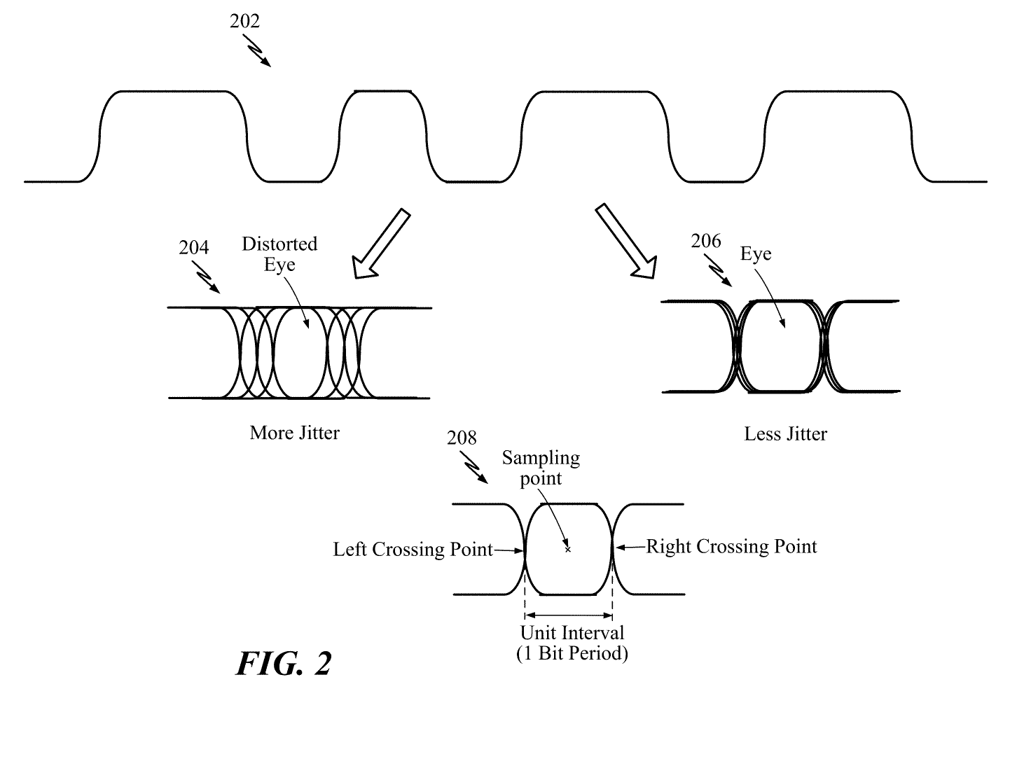

FIG. 2 illustrates the creation of exemplary eye patterns. Eye patterns are an effective method of measuring time distortion of a signal through a transmission medium or circuit. The eye pattern is often displayed in an oscilloscope. An exemplary signal 202 is illustrated. An eye pattern is the superposition, over one unit interval, of all the Zero-to-One and One-to-Zero transitions of such exemplary signal 202, each preceded and followed by various combinations of One and Zero, and also constant One and Zero levels. An eye pattern 204 and 206 is formed when the superposition of signal unit intervals 208 align with each other (e.g., indicating no jitter distortion). On the other hand, a distorted eye pattern 204 or no eye pattern is formed when jitter is present.

### Step Response to Ascertain Jitter

Rather than using a pseudo-random sequence generator within a simulator, which results in a time-consuming process to identify worst-case scenarios for jitter, a set of step functions may be used instead.

In the case of inter/intra chip interconnects, jitter may be induced by a wideband frequency signal as an input to a simulated interconnect. For instance, loss and distortion transmission line effect is significant when the signal frequency is up to 10 Gbp. The output from the simulated interconnect is a single step response that includes all the frequency information of the step input. As a result, with the step function input, output signals can have primary parameters to determine and/or predict jitter.

In the case of a clock or data path with nonlinear elements (e.g., transistors, etc.), jitter may be induced by a low frequency signal as an input. In such types of non-linear elements, jitter is mainly contributed by power supply noise. The worst-case period jitter is bounded by a maximum delay difference. There exists a linear relationship between the maximum delay difference and the worst case period jitter.

Because the worst case jitter conditions for different components or elements are known to some extent (e.g., low frequency input signal versus wideband frequency input signal, etc.), it is possible to synthesize or construct an approximate worst case input signal based on a set of step functions and a noise level.

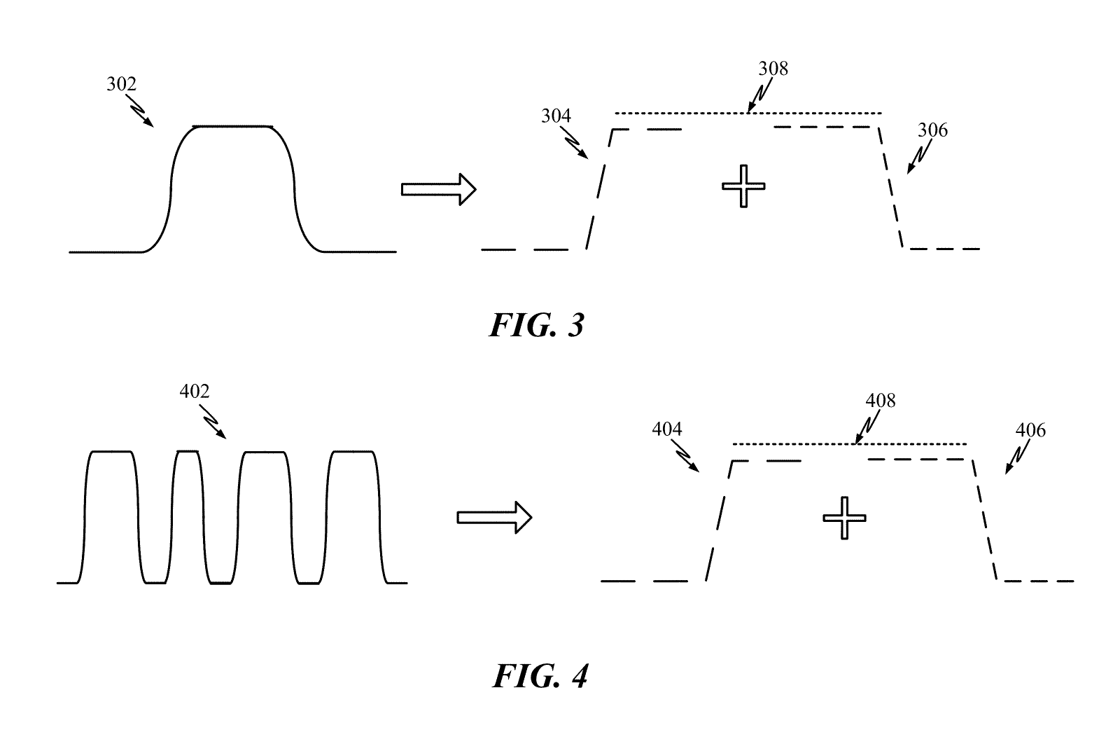

FIG. 3 illustrates how a binary signal 302 corresponding to one bit may be decomposed into a first step function 304, a second step function 306, and a DC noise level 308.

FIG. 4 illustrates how a binary signal 402 corresponding to multiple bits may be decomposed into a first step function 404, a second step function 406, and a DC noise level 408. This observation may be used to replace, for simulation purposes, a binary signal with at least two step functions and a noise level.

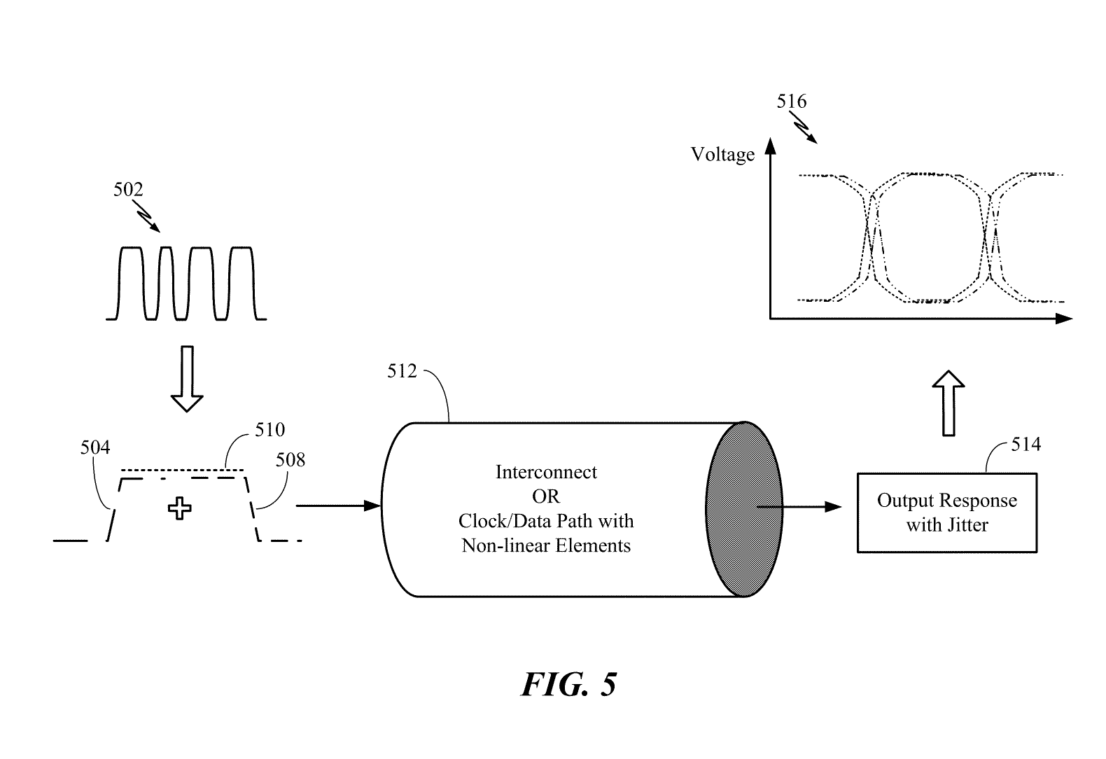

FIG. 5 is a diagram illustrating how a digital signal 502 may be replaced by a set of input functions 504, 508, 510 that serve as input to a simulated interconnect or clock/data path with non-linear elements 512 to obtain an output response 514. From this output response 514 jitter 516 may be predicted or estimated by, for example, comparing the output of two step input functions.

### Exemplary Jitter Prediction Method for Interconnect

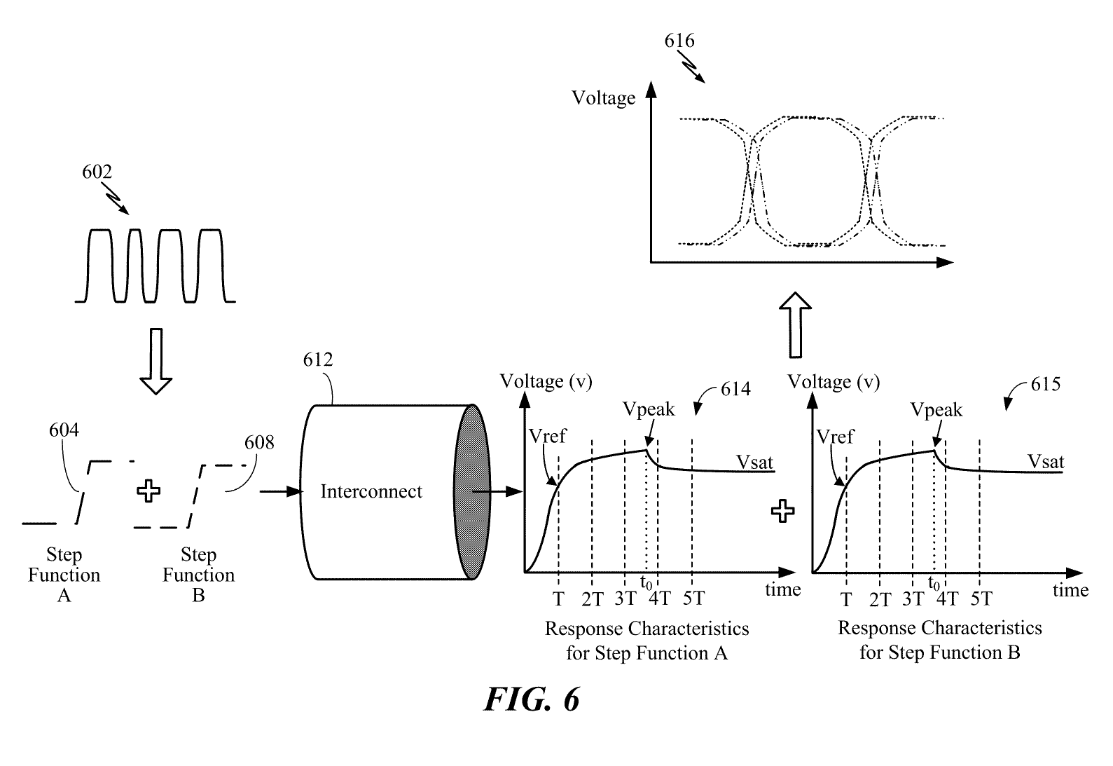

FIG. 6 is a diagram illustrating how a digital signal 602 may be replaced by a set of input functions 604, 608 that serve as input to a simulated interconnect to predict jitter. In this example, the input signal is tailored as a wideband frequency signal since such signal tends to provide the worst case jitter for interconnects. Consequently, two step functions 604 and 608 are sent sequentially through the interconnect 612. For each step function 604 and 608, a characteristic output response 614 and 615 (e.g., voltage over time) is obtained. By comparing two or more characteristic responses 614 and 615 from two separate step functions 604 and 608, jitter for the interconnect 612 may be predicted. For instance, the resulting output step function responses may be superimposed as an eye diagram 616. Jitter for the interconnect may then be obtained from the eye pattern and/or eye voltages.

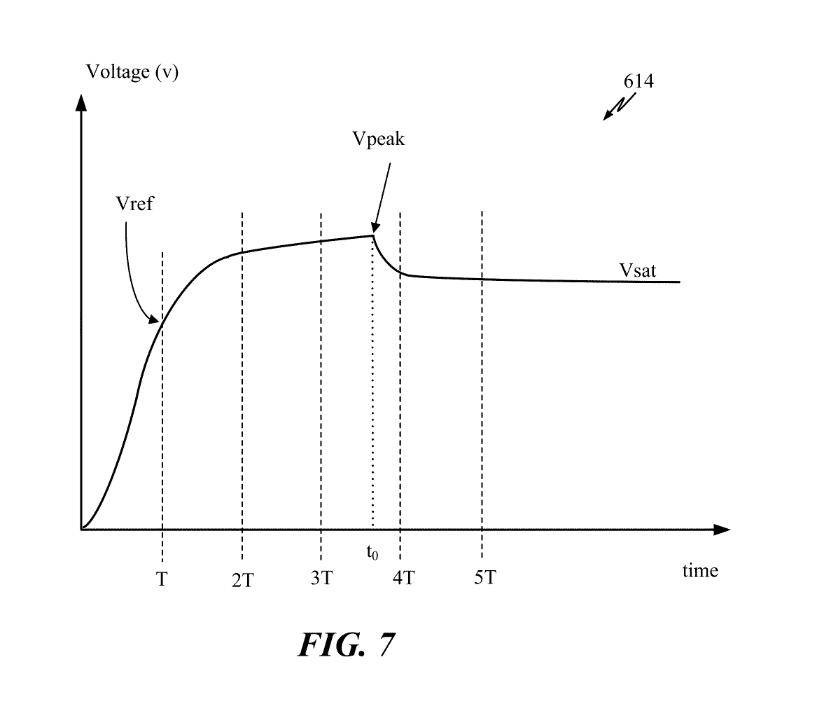

FIG. 7 illustrates an output response 614 graph of FIG. 6. The output response 614 may be estimated according to the following equations:

$$\frac{1 - {V}_{f}}{{R}_{Z}} = \frac{{V}_{f}}{{Z}_{0}}$$

$${V}_{atten} ( f ) = {V}_{i n} {e}^{- α ( f ) l}$$

$$Vref = {V}_{atten} ( f = \frac{1}{2 T} ) \frac{2 {Z}_{t}}{{Z}_{0} + {Z}_{d} + {Z}_{t}}$$

$$Vpeak = {V}_{atten} ( f -> 0 ) \frac{2 {Z}_{t}}{{Z}_{0} + {Z}_{d} + {Z}_{t}}$$

$${V}_{sat} = {V}_{out i n D C path}$$

$$α \approx \frac{1}{2} ( R ( f ) \sqrt{\frac{C}{L}} )$$

where,
Vref=V(T)=reference or threshold voltage value at a time period T;
Vpeak=maximum/peak voltage of the step function response;
Vsat=final saturation voltage of the step function response.
   The reference or threshold voltage Vref represents the rise time for the step function response and is obtained at a first time period (T). The maximum voltage Vpeak is the maximum voltage of the step function response, and the saturation voltage Vsat is its saturation voltage.

The eye voltage Veye associated with a step function may be estimated as:

Veye=Vsat−2(Vpeak−Vref)=the voltage for an eye pattern.

Jitter for an interconnect may then be estimated, approximated, or obtained by comparing the eye voltage for two or more step function responses 614 and 615 (FIG. 6). For instance, for a first step function response 614, a first eye voltage Veye_{StepFuncA} may be obtained. Similarly, for a second step function response 615, a second eye voltage Veye_{StepFuncB} may be obtained. Jitter for the interconnect 612 may then be estimated as (for example):

jitter_{interconnect}=abs(Veye_{StepFuncA}−Veye_{StepFuncB}).

Exemplary Jitter Prediction Method for Clock/Data Path with Nonlinear Element

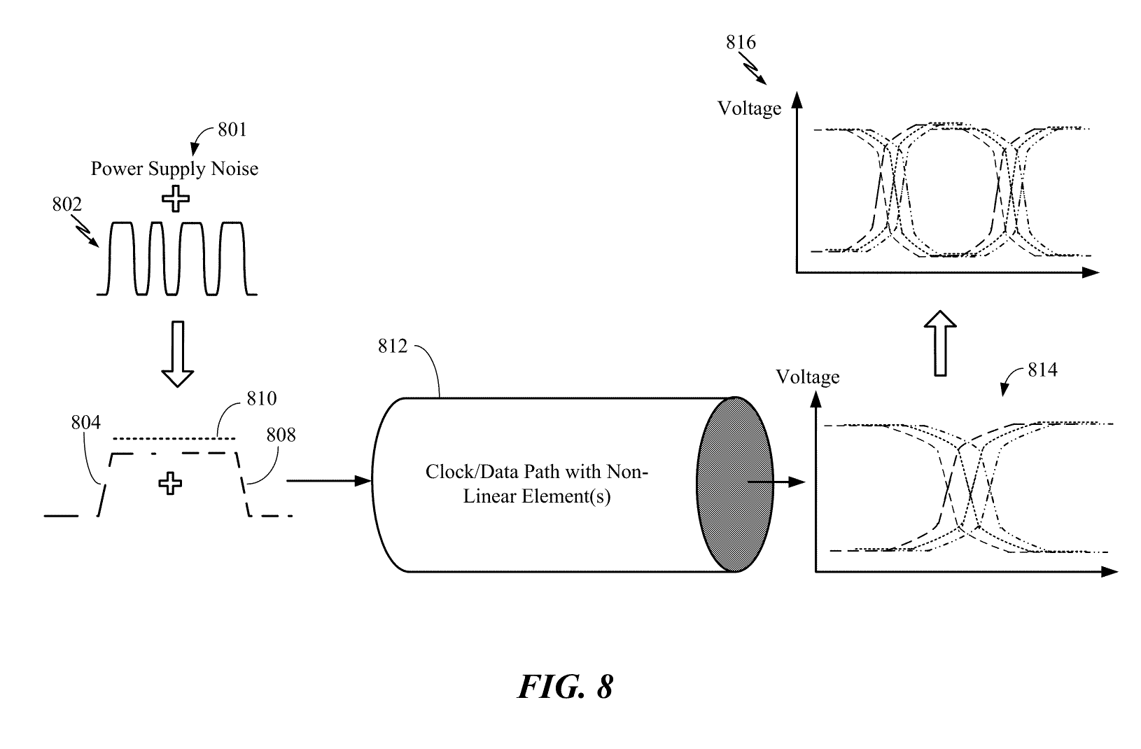

FIG. 8 is a diagram illustrating how a digital signal 802 and power supply noise 801 may be replaced by a set of input step functions 804, 808 and a DC noise signal 810 that serve as input to a simulated clock/data path with non-linear elements 812 to predict jitter from and eye pattern 816. In this example, the input signal is tailored as a low frequency signal since such signal tends to provide the worst case jitter for clock/data paths with non-linear elements. Consequently, two step functions 804 and 808 and a DC noise signal 810 are sent sequentially through the clock/data path 812. For each step function 804 and 808, a characteristic output response 814 (e.g., voltage over time) is obtained. By comparing two or more characteristic responses from two separate step functions 804 and 808, jitter for the clock/data path 812 may be predicted.

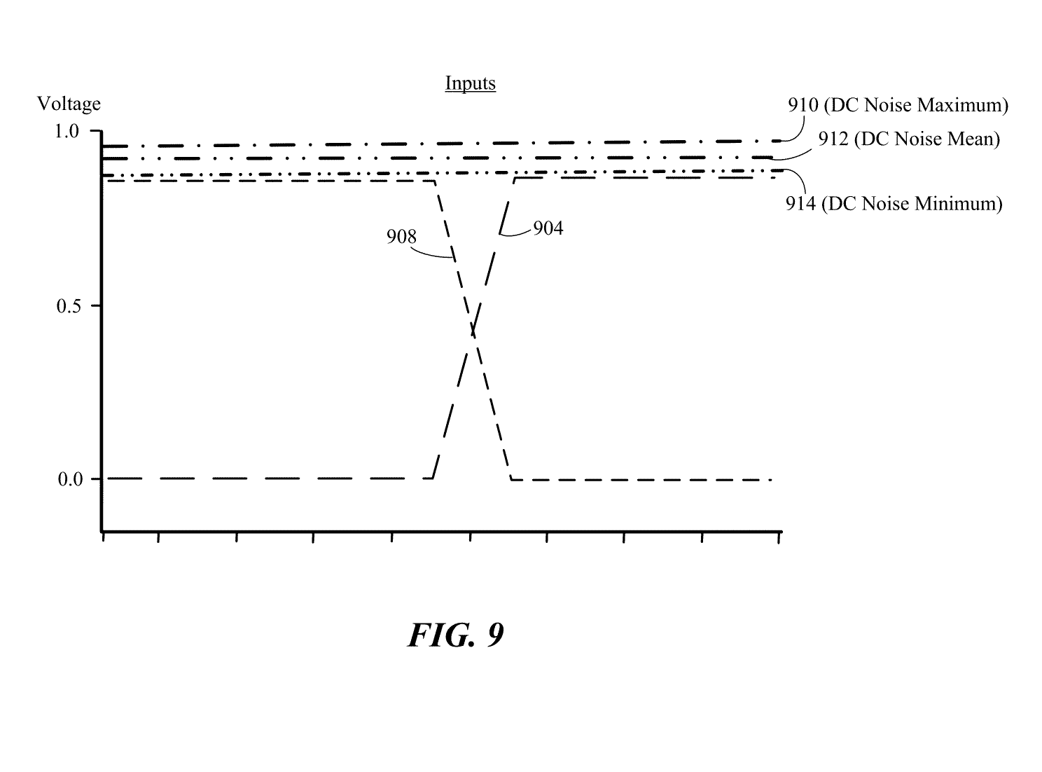

FIG. 9 illustrates an example of input step signals and DC noise signals (e.g., power supply noise) that may be used to predict jitter. As illustrated, two step functions 904 and 908 and a maximum DC noise 910, mean DC noise 912, and minimum DC noise 914 may be used as inputs to generate a plurality of corresponding responses.

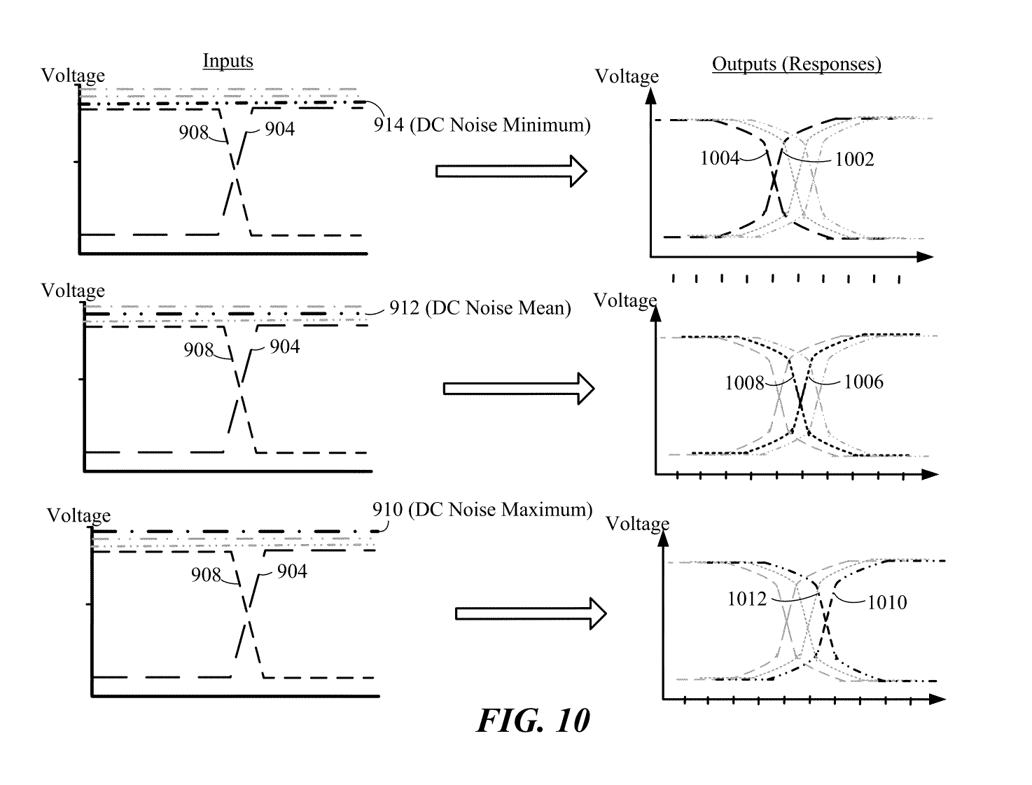

FIG. 10 illustrates how the input signals of FIG. 9 may be used to generate a plurality of output responses. For the minimum DC noise signal 914 and a first step function 904, a first response 1002 is obtained. For the minimum DC noise signal 914 and a second step function 908, a second response 1004 is obtained.

Similarly, for the mean DC noise signal 912 and the first step function 904, a third response 1006 is obtained. For the mean DC noise signal 912 and the second step function 908, a fourth response 1008 is obtained.

Similarly, for the maximum DC noise signal 910 and the first step function 904, a fifth response 1010 is obtained. For the maximum DC noise signal 910 and the second step function 908, a sixth response 1012 is obtained.

In this manner, six different output responses 1002, 1004, 1006, 1008, 1010, and 1012 are obtained. The differences between these output responses may be used to ascertain or estimate jitter.

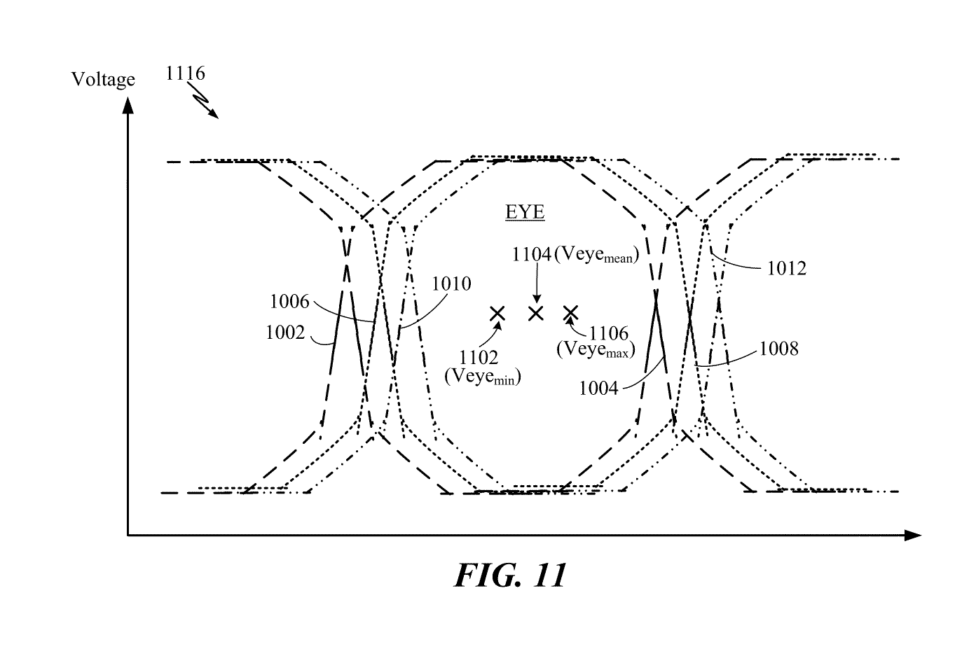

FIG. 11 illustrates an eye diagram 1116 formed from the responses 1002, 1004, 1006, 1008, 1010, and 1012 of FIG. 10. Here, a plurality of eye patterns may be formed by the superposition of the responses 1002/1004, 1006/1008, and/or 1010/1012. From a characteristic output response for each step function input, a saturation voltage Vsat, a reference/threshold voltage Vref, and a maximum/peak voltage Vpeak may be obtained as discussed in FIG. 7. A voltage Veye for each eye pattern is obtained as Veye=Vsat−2(Vpeak−Vref). Thus, a first eye is formed by responses 1002 and 1004 having a first eye voltage Veyeₘᵢₙ 1102, a second eye is formed by responses 1006 and 1008 having a second eye voltage Veyeₘₑₐₙ 1104, and a third eye is formed by responses 1010 and 1012 having a third eye voltage Veyeₘₐₓ 1106. Jitter may then be obtained, estimated, or calculated as:

jitter=max{(Veyeₘₐₓ−Veye (Veyeₘₑₐₙ), (Veyeₘₑₐₙ−V_{eye}ₘᵢₙ)},

where the function “max” selects the maximum value between Veyeₘₐₓ−Veyeₘₑₐₙ and Veye_{mean mean}−Veyeₘᵢₙ.

There exist linear relationship between maximum delay difference (MDD) and worst case period jitter (WCPJ) that may be defined as:

$$\frac{MDD}{WCPJ} = \frac{M}{3 P} * \frac{{\sum }_{i = 1}^{n} {C}_{Li}}{\sqrt{{\sum }_{i = 1}^{n} {R}_{j}^{2} {C}_{Li}^{2}}}$$

This equation may be rewritten as follows:

$$MCPJ = PARA * MDD$$

$$where$$

$$WCPJ = {[ {WCPJ}_{1} , {WCPJ}_{2} , … , {WCPJ}_{n} ]}^{T}$$

$$MDD = [ {MDD}_{1} , {MDD}_{2} , … , {MDD}_{n} ]$$

$$PARA = diag [ {PARA}_{1} , {PARA}_{2} , … , {PARA}_{n} ]$$

$$Where$$

$${PARA}_{i} = \frac{3 P}{M} * \frac{\sqrt{{\sum }_{j = 1}^{i} {C}_{Lj}}}{{\sum }_{j = 1}^{i} {C}_{Lj}}$$

These observations may be used in defining the step functions used as inputs in the digital simulator to predict the worst-case jitter.

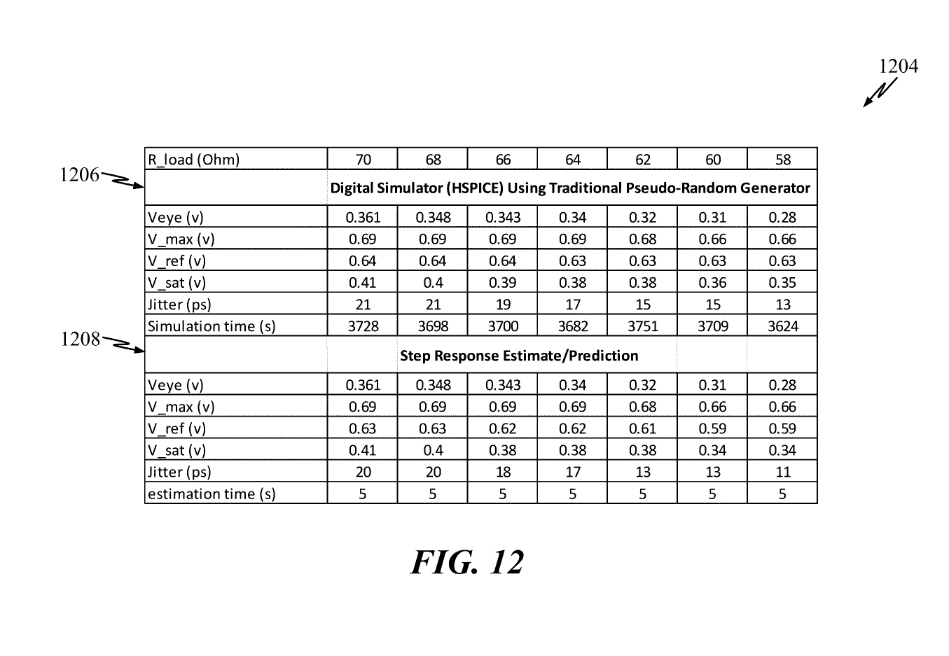

FIG. 12 illustrates the results of a simulation model for an inter/intra chip interconnect path. The interconnect path may be characterized as a voltage source followed by a parallel load resistance R_{load} and capacitance C_{load}, followed by a line impedance and capacitance in series, and followed by a termination resistance. A table 1204 of voltage-eye (Veye) and jitter results for such simulated interconnect path are shown for a typical digital simulator 1206 (using a pseudo-random sequence generator to generate an input) as well as for the step function input approach 1208 illustrated in FIGS. 3-11. As can be appreciated by comparing the values Veye, Vpeak, Vref, Vsat, and jitter the results obtained for the typical approach (e.g., pseudo-random sequence generator) and the step function inputs correlate very closely with each other, but the step function inputs produce the results with minimal simulation times.

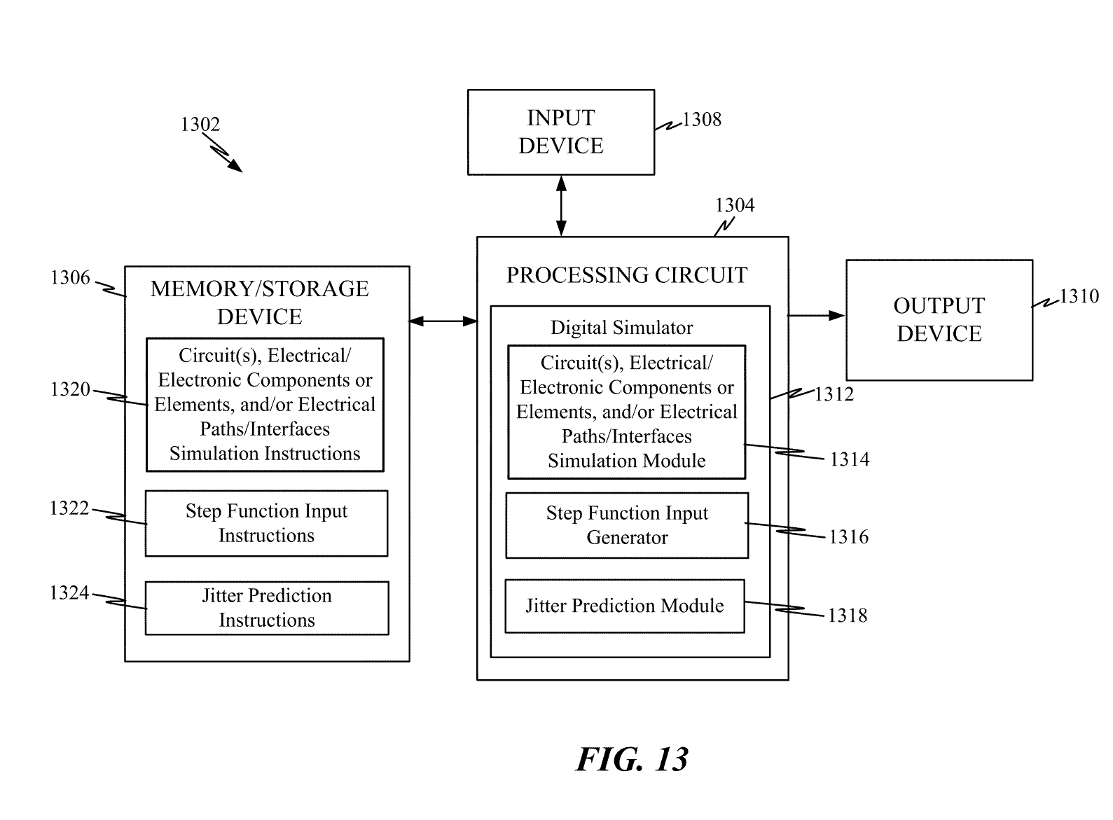

FIG. 13 is a block diagram illustrating a device that implements a digital simulator in which the input signals are generated from step functions. The device 1302 may include a processing circuit 1304 (e.g., processing unit, etc.) coupled to a memory/storage device 1306, an input device 1308 (e.g., keyboard, etc.) and an output device 1310 (e.g., display monitor, etc.). The processing circuit 1304 may be adapted to execute a digital simulator 1312 that may serve to simulate the characteristics and response of circuit(s), electrical/electronic components or elements, and/or electrical paths/interfaces. In one example, the digital simulator 1312 may include a circuit(s), electrical/electronic components or elements, and/or electrical paths/interfaces simulation module 1314, a step function input generator 1316, and a jitter prediction module 1318. For instance, the step function input generator 1316, and a jitter prediction module 1318 may operate to perform one or more of the features illustrated in FIGS. 1-12 and 14. The memory/storage device 1306 may include circuit(s), electrical/electronic components or elements, and/or electrical paths/interfaces instructions 1320, step function input instructions 1322, and jitter prediction instructions 1324.

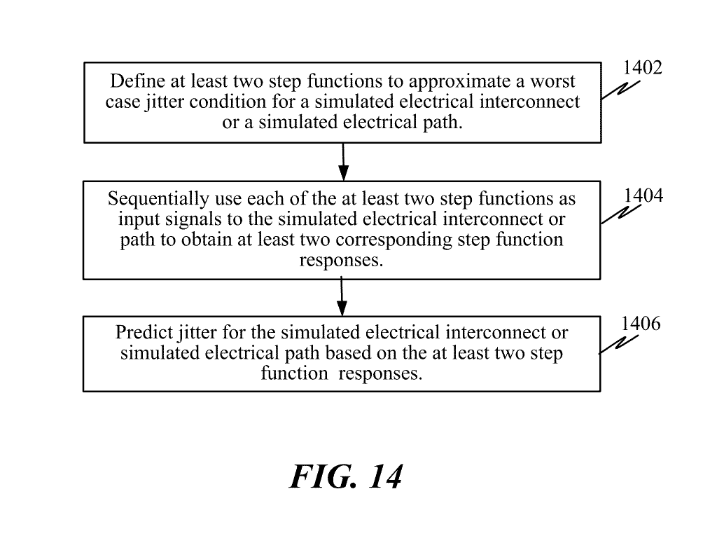

FIG. 14 is a flow diagram illustrating a method operational within a simulator for substituting a pseudo-random number generated input signal with two or more step functions to characterize or predict jitter for a circuit, component, element, path, or interconnect being simulated. At least two step functions are defined to approximate a worst case jitter condition for a simulated electrical interconnect or a simulated electrical path 1402. The at least two step functions are sequentially used as input signals to the simulated electrical interconnect or path to obtain at least two corresponding step function responses 1404. Jitter for the simulated electrical interconnect or simulated electrical path may be predicted based on the at least two step function responses 1406.

In one example, a rise time for the at least two step functions may be adjusted to approximate a worst case jitter condition. In another example, a noise signal may be added to the at least two step functions to approximate a worst case jitter condition.

In one example, the at least two step functions include a first step function and a second step function. Predicting jitter may include: (a) estimating a first reference voltage, a first saturation voltage, and a first peak voltage for a first response corresponding to the first step function, (b) obtaining a first eye voltage based on the first reference voltage, the first saturation voltage, and the first peak voltage, (c) estimating a second reference voltage, a second saturation voltage, and a second peak voltage for a second response corresponding to the second step function, (d) obtaining a second eye voltage based on the second reference voltage, the second saturation voltage, and the second peak voltage, and/or (e) estimating the jitter based on a difference between the first eye voltage and the second eye voltage.

In another example, the at least two step functions may include a first step function and a second step function. The method may further comprise: (a) adding a plurality of different noise signals to distinct instances of the first step function and second step function, where each of the different noise signals approximate different levels of noise, and/or (b) using distinct instances of the first step function and second step function as inputs to the simulated electrical path. Predicting jitter may include: (a) obtaining a plurality of distinct responses for the distinct instances of the first step function and second step function; (b) estimating a reference voltage, a saturation voltage, and a peak voltage for each response corresponding to each instance of the first and second step functions; (c) obtaining eye voltages for each response based on the first reference voltage, the first saturation voltage, and the first peak voltage; and/or (d) estimating the jitter based on a maximum difference between the different pairs of eye voltages.

In some instances, the at least two step functions may be defined with wideband frequency signal characteristics when used as input signals to the simulated electrical interconnect.

In other instances, the at least two step functions may be defined with low frequency signal characteristics when used as input signals to the simulated electrical path.

The at least two step functions used for the simulated electrical interconnect may be distinct from the at least two step functions used for the simulated electrical path. The at least two step functions may replace a pseudo-random sequence as input signals to the simulated electrical interconnect or path.

Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on a computer-readable storage medium. The computer-readable storage medium may be a non-transitory computer-readable storage medium. A non-transitory computer-readable storage medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable storage medium may also include, by way of example, a carrier wave, a transmission line, and any other suitable medium for transmitting software and/or instructions that may be accessed and read by a computer. The computer-readable storage medium may be embodied in a computer program product.

Moreover, a storage medium may represent one or more devices for storing data, including read-only memory (ROM), random access memory (RAM), magnetic disk storage mediums, optical storage mediums, flash memory devices and/or other machine-readable mediums and, processor-readable mediums, and/or computer-readable mediums for storing information. The terms “machine-readable medium”, “computer-readable medium”, and/or “processor-readable medium” may include, but are not limited to non-transitory mediums such as portable or fixed storage devices, optical storage devices, and various other mediums capable of storing, containing or carrying instruction(s) and/or data. Thus, the various methods described herein may be fully or partially implemented by instructions and/or data that may be stored in a “machine-readable medium”, “computer-readable medium”, and/or “processor-readable medium” and executed by one or more processors, machines, and/or devices.

One or more of the components, steps, features, and/or functions illustrated in the Figures may be rearranged and/or combined into a single component, step, feature, or function or embodied in several components, steps, or functions. Additional elements, components, steps, and/or functions may also be added without departing from novel features disclosed herein. The apparatus, devices, and/or components illustrated in the Figures may be configured to perform one or more of the methods, features, or steps described in the Figures. The novel algorithms described herein may also be efficiently implemented in software and/or embedded in hardware.

In addition, it is noted that the embodiments may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a function, a procedure, a subroutine, a subprogram, etc. When a process corresponds to a function, its termination corresponds to a return of the function to the calling function or the main function.

Moreover, a storage medium may represent one or more devices for storing data, including read-only memory (ROM), random access memory (RAM), magnetic disk storage mediums, optical storage mediums, flash memory devices, and/or other machine-readable mediums for storing information. The term “machine readable medium” includes, but is not limited to portable or fixed storage devices, optical storage devices, wireless channels and various other mediums capable of storing, containing, or carrying instruction(s) and/or data.

Furthermore, embodiments may be implemented by hardware, software, firmware, middleware, microcode, or any combination thereof. When implemented in software, firmware, middleware, or microcode, the program code or code segments to perform the necessary tasks may be stored in a machine-readable medium such as a storage medium or other storage(s). A processor may perform the necessary tasks. A code segment may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, etc.

The various illustrative logical blocks, modules, circuits, elements, and/or components described in connection with the examples disclosed herein may be implemented or performed with a general purpose processor, a digital signal processor (DSP), an application specific integrated circuit (ASIC), a field programmable gate array (FPGA) or other programmable logic component, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing components, e.g., a combination of a DSP and a microprocessor, a number of microprocessors, one or more microprocessors in conjunction with a DSP core, or any other such configuration.

The methods or algorithms described in connection with the examples disclosed herein may be embodied directly in hardware, in a software module executable by a processor, or in a combination of both, in the form of processing unit, programming instructions, or other directions, and may be contained in a single device or distributed across multiple devices. A software module may reside in RAM memory, flash memory, ROM memory, EPROM memory, EEPROM memory, registers, hard disk, a removable disk, a CD-ROM, or any other form of storage medium known in the art. A storage medium may be coupled to the processor such that the processor can read information from, and write information to, the storage medium. In the alternative, the storage medium may be integral to the processor.

Those of skill in the art would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system.

The various features of the invention described herein can be implemented in different systems without departing from the invention. It should be noted that the foregoing embodiments are merely examples and are not to be construed as limiting the invention. The description of the embodiments is intended to be illustrative, and not to limit the scope of the claims. As such, the present teachings can be readily applied to other types of apparatuses and many alternatives, modifications, and variations will be apparent to those skilled in the art.

What is claimed is:

1. A method operational within a simulation environment, comprising
defining at least two step functions to approximate a worst case jitter condition for a simulated electrical interconnect or a simulated electrical path;
sequentially using each of the at least two step functions as input signals to the simulated electrical interconnect or path to obtain at least two corresponding step function responses; and
predicting jitter for the simulated electrical interconnect or simulated electrical path based on the at least two step function responses.

2. The method of claim 1, wherein a rise time for the at least two step functions is adjusted to approximate a worst case jitter condition.

3. The method of claim 1, wherein a noise signal is added to the at least two step functions to approximate a worst case jitter condition.

4. The method of claim 1, wherein the at least two step functions include a first step function and a second step function, and predicting jitter includes:
estimating a first reference voltage, a first saturation voltage, and a first peak voltage for a first response corresponding to the first step function;
obtaining a first eye voltage based on the first reference voltage, the first saturation voltage, and the first peak voltage;
estimating a second reference voltage, a second saturation voltage, and a second peak voltage for a second response corresponding to the second step function;
obtaining a second eye voltage based on the second reference voltage, the second saturation voltage, and the second peak voltage; and
estimating the jitter based on a difference between the first eye voltage and the second eye voltage.

5. The method of claim 1, wherein the at least two step functions include a first step function and a second step function, and further comprising:
adding a plurality of different noise signals to distinct instances of the first step function and second step function, where each of the different noise signals approximate different levels of noise; and
using distinct instances of the first step function and second step function as inputs to the simulated electrical path.

6. The method of claim 5, wherein predicting jitter includes:
obtaining a plurality of distinct responses for the distinct instances of the first step function and second step function;
estimating a reference voltage, a saturation voltage, and a peak voltage for each response corresponding to each instance of the first and second step functions;
obtaining eye voltages for each response based on the first reference voltage, the first saturation voltage, and the first peak voltage; and
estimating the jitter based on a maximum difference between the different pairs of eye voltages.

7. The method of claim 1, wherein the at least two step functions are defined with wideband frequency signal characteristics when used as input signals to the simulated electrical interconnect.

8. The method of claim 1, wherein the at least two step functions are defined with low frequency signal characteristics when used as input signals to the simulated electrical path.

9. The method of claim 1, wherein the at least two step functions used for the simulated electrical interconnect are distinct from the at least two step functions used for the simulated electrical path.

10. The method of claim 1, wherein the at least two step functions replace a pseudo-random sequence as input signals to the simulated electrical interconnect or path.

11. A processor-readable non-transitory medium comprising instructions operational within a simulation environment, which when executed by a processing circuit causes the processing circuit to:
define at least two step functions to approximate a worst case jitter condition for a simulated electrical interconnect or a simulated electrical path;
sequentially use each of the at least two step functions as input signals to the simulated electrical interconnect or path to obtain at least two corresponding step function responses; and
predict jitter for the simulated electrical interconnect or simulated electrical path based on the at least two step function responses.

12. The processor-readable non-transitory medium of claim 11, wherein a rise time for the at least two step functions is adjusted to approximate a worst case jitter condition.

13. The processor-readable non-transitory medium of claim 11, wherein a noise signal is added to the at least two step functions to approximate a worst case jitter condition.

14. The processor-readable non-transitory medium of claim 11, wherein the at least two step functions include a first step function and a second step function, and predicting jitter includes instructions to:
estimate a first reference voltage, a first saturation voltage, and a first peak voltage for a first response corresponding to the first step function;
obtain a first eye voltage based on the first reference voltage, the first saturation voltage, and the first peak voltage;
estimate a second reference voltage, a second saturation voltage, and a second peak voltage for a second response corresponding to the second step function;
obtain a second eye voltage based on the second reference voltage, the second saturation voltage, and the second peak voltage; and
estimate the jitter based on a difference between the first eye voltage and the second eye voltage.

15. The processor-readable non-transitory medium of claim 11, wherein the at least two step functions include a first step function and a second step function, and further comprising instructions to:
add a plurality of different noise signals to distinct instances of the first step function and second step function, where each of the different noise signals approximate different levels of noise; and
use distinct instances of the first step function and second step function as inputs to the simulated electrical path.

16. The processor-readable non-transitory medium of claim 15, wherein predicting jitter includes instructions to:
obtain a plurality of distinct responses for the distinct instances of the first step function and second step function;
estimate a reference voltage, a saturation voltage, and a peak voltage for each response corresponding to each instance of the first and second step functions;
obtain eye voltages for each response based on the first reference voltage, the first saturation voltage, and the first peak voltage; and
estimate the jitter based on a maximum difference between the different pairs of eye voltages.

17. The processor-readable non-transitory medium of claim 11, wherein the at least two step functions are defined with wideband frequency signal characteristics when used as input signals to the simulated electrical interconnect.

18. The processor-readable non-transitory medium of claim 11, wherein the at least two step functions are defined with low frequency signal characteristics when used as input signals to the simulated electrical path.

19. The processor-readable non-transitory medium of claim 11, wherein the at least two step functions used for the simulated electrical interconnect are distinct from the at least two step functions used for the simulated electrical path.

20. The processor-readable non-transitory medium of claim 11, wherein the at least two step functions replace a pseudo-random sequence as input signals to the simulated electrical interconnect or path.
